(19) United States
(12) Patent Application Publication
(10) Pub. No.: US 2024/0302746 A1
(43) Pub. Date: Sep. 12, 2024

(54) RESIST FILM THICKENING COMPOSITION AND METHOD FOR MANUFACTURING THICKENED PATTERN

(71) Applicant: MERCK PATENT GMBH, Darmstadt (DE)

(72) Inventor: Hirokazu IKEDA, Kakegawa-shi (JP)

(21) Appl. No.: 18/277,428

(22) PCT Filed: Feb. 15, 2022
(86) PCT No.: PCT/EP2022/053584

§ 371 Date: Aug. 16, 2023

(30) Foreign Application Priority Data
Feb. 18, 2021 (JP) 2021-024064

(51) Int. Cl. G03F 7/11; G03F 7/00; G03F 7/004; G03F 7/16; G03F 7/20

(52) U.S. Cl. CPC G03F 7/11; G03F 7/0005; G03F 7/0048; G03F 7/168; G03F 7/2004

(57) ABSTRACT

[Problem] To provide a resist film thickening composition. [Means for Solution] The resist film thickening composition comprises a polymer (A), a nitrogen-containing compound (B) and a solvent (C): wherein the nitrogen-containing compound (B) is a 5- or 6-membered ni-trogen-containing unsaturated heterocyclic compound substituted with one or two substituents selected from the group consisting of hydroxy, amino, C₁₋₄ hydroxyalkyl and C₁₋₄ aminoalkyl.

### BACKGROUND OF THE INVENTION

### Technical Field

The present invention relates to a resist film thickening composition and a method for manufacturing a thickened pattern.

### Background Art

In recent years, in the manufacture of semiconductor devices and liquid crystal display devices, pattern formation using a resist has been performed. As a method of miniaturizing a resist pattern, a method of effectively manufacturing a fine resist pattern having of a resolution limit or less, which comprises forming a resist pattern using a resist composition, thereafter applying a coating layer on the resist pattern, and then heating or the like, to form a mixing layer between the coating layer and the resist pattern, and then removing a part of the coating layer to thicken the resist pattern and, as a result, reducing the separation size of the resist pattern or the hole aperture size to achieve miniaturization of the resist pattern, has been proposed.

The resist process of the liquid crystal display device is required to have high sensitivity in order to achieve high throughput. The light source to be used is a radiation having a wavelength of 300 nm or more, such as 365 nm (i-line), 405 nm (h-line) and 436 nm (g-line), and a wavelength mixture of these is used in particular. The shape of the resist pattern is preferably a rectangle in the semiconductor manufacturing field, but an inclined (hereinafter referred to as “taper”) shape on the inner side surface of a hole portion or the like is sometimes preferred since it is good when used in the subsequent processing.

Recently, technological development for high-performance LCD called system LCD has been actively conducted, and further resolution enhancement of resist pattern is required. In general, it is necessary to use a light source of short wavelength or to use an exposure process of high NA (numerical aperture) in order to increase the resolution (resolution limit) of the resist pattern. However, in the liquid crystal display device manufacturing field, it was difficult to shorten the exposure wavelength than before by changing the light source device, and it was also difficult to achieve high NA from the viewpoint of throughput improvement.

Patent Documents 1 and 2 have proposed methods for manufacturing a fine pattern by applying a fine pattern forming composition on a developed resist pattern.

For the purpose of providing a positive resist composition, which is effective for manufacturing semiconductor devices, liquid crystal devices, etc. and which has no etching defects due to sublimates and less change in sensitivity and remaining film ratio with time and also can form a resist pattern having good adhesion to a substrate having a silicon oxide film or a silicon nitride film, Patent Document 3 studies to add a predetermined pyridine derivative to a positive resist composition.

### PRIOR ART DOCUMENTS

### Patent Documents

[Patent document 1] JP 2019-078810 A
[Patent document 2] JP 2019-078812 A
[Patent document 3] JP 3024695 B

### SUMMARY OF THE INVENTION

### Problems to be Solved by the Invention

Under the technical background as described above, the present inventors considered that there are one or more problems still need improvements with respect to manufacturing a resist pattern. Examples of these include the following: thickening a resist pattern; increasing the shrink amount of a resist pattern; improving the adhesion between an underlying substrate and a resist pattern; effectively manufacturing a resist pattern of a resolution limit or less, which is suitable for the use in the field of display devices; precisely manufacturing a fine pattern of a resolution limit or less while maintaining the shape of a resist pattern having a taper shape; preventing an etchant from entering from the edge of a thickened resist pattern mask; obtaining a composition having good solubility to components; and obtaining a composition that does not cause uneven concentration of the components or turbidity, due to insoluble substances.

### Means for Solving the Problems

The resist film thickening composition according to the present invention comprises a polymer (A), a nitrogen-containing compound (B) and a solvent (C): wherein
the nitrogen-containing compound (B) is a 5- or 6-membered nitrogen-containing unsaturated heterocyclic compound substituted with one or two substituents selected from the group consisting of hydroxy, amino, C₁₋₄ hydroxyalkyl and C₁₋₄ aminoalkyl.

The method for manufacturing a thickened pattern according to the present invention comprises the following steps:
(1) a step of applying a resist composition above a substrate to form a resist film;
(2a) a step of subjecting the resist film to exposure; (2b) a step of developing the resist film to form a resist pattern;
(2c) a step of applying above-mentioned resist film thickening composition on the surface of the resist pattern to form a resist film thickening layer; (3) a step of heating the resist pattern and the resist film thickening layer to cure the regions of the resist film thickening layer in the vicinity of the resist pattern and to form an insolubilized layer; and
(4) a step of removing the uncured regions of the resist film thickening layer:
provided that the order of steps (2a), (2b) and (2c) is in any order, and (2a) is performed before (2b).

The method for manufacturing a processed substrate according to the present invention comprises the following steps:
a step of preparing a substrate above which a thickened pattern is formed by the above-mentioned method; and (5) a step of processing the substrate by etching.

### Effects of the Invention

According to the present invention, one or more of the following effects can be desired:

thickening a resist pattern; obtaining a resist pattern useful as an etching mask; obtaining a resist pattern having high adhesion to an underlying substrate; it is possible to form a fine pattern while maintaining the shape of a resist pattern having a taper shape; a dimensional reduction ratio of a space portion or a hole portion is high; it is possible to form a pattern of a resolution limit or less in a good and economical manner; it is possible to manufacture a finer pattern with a low amount of exposure; preventing an etchant from entering from the edge of a thickened resist pattern mask; solubility of solutes in a solvent (preferably water) is good; and uneven concentration of the components due to insoluble substances does not cause.

### BRIEF DESCRIPTION OF THE DRAWINGS

FIG. 1: Explanatory drawing of a method for manufacturing a fine pattern.

### DETAILED DESCRIPTION OF THE INVENTION

### Mode for Carrying Out the Invention

### Definition

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has a plural types of repeating units, these repeating units copolymerize. These copolymerization may be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (C) or another component.

Hereinafter, embodiments of the present invention are described in detail.

### [Resist Film Thickening Composition]

The resist film thickening composition according to the present invention comprises a polymer (A), a nitrogen-containing compound (B) having a certain structure, and a solvent (C).

In a preferred embodiment of the present invention, the resist film thickening composition is a fine pattern forming composition. The fine pattern forming composition thickens the resist pattern by thickening the resist pattern, and as a result, reduces the separation size and hole opening size of the resist pattern.

The viscosity of the resist film thickening composition according to the present invention is preferably 1 to 120 cP; more preferably 10 to 80 cP. Here, the viscosity is measured by a capillary viscometer at 25° C.

### (A) Polymer

The polymer (A) used in the present invention is not particularly limited as long as it has a good affinity with the resist pattern, and is preferably selected from the group consisting of polyvinyl acetal resin, polyvinyl alcohol resin, polyacrylic acid resin, polyvinylpyrrolidone resin, polyethylene oxide resin, poly-N-vinylformamide resin, oxazoline-containing water-soluble resin, aqueous urethane resin, polyallylamine resin, polyethyleneimine resin, polyvinylamine resin, water-soluble phenol resin, water-soluble epoxy resin, polyethyleneimine resin, and copolymers of any of these, and styrene-maleic acid copolymer. More preferably, it includes polyvinyl acetal resin, polyallylamine resin, polyvinyl alcohol oxazoline-containing water-soluble resin or polyvinyl alcohol-polyvinylpyrrolidone copolymer,

The content of the polymer (A) is preferably 5 to 30 mass %; more preferably 7 to 20 mass %; further preferably 8 to 15 mass %, based on the total mass of the resist film thickening composition.

In one embodiment of the present invention, the mass average molecular weight (Mw) of the polymer (A) is 1,000 to 1,000,000; preferably 2,000 to 200,000; more preferably 3,000 to 100,000; further more preferably 5,000 to 50,000. Here, in the present invention, Mw means a mass average molecular weight in terms of polystyrene, which is measured by the gel permeation chromatography based on polystyrene. The same applies to the following.

### (B) Nitrogen-Containing Compound

The nitrogen-containing compound (B) is a 5- or 6-membered nitrogen-containing unsaturated heterocyclic compound substituted with one or two substituents selected from the group consisting of hydroxy, amino, C₁₋₄ hydroxyalkyl and C₁₋₄ aminoalkyl. Preferably, the nitrogen-containing unsaturated heterocyclic compound has aromaticity. In a preferred embodiment, the nitrogen-containing compound (B) is an adhesion enhancing component. Although not to be bound by theory, it is assumed that the nitrogen-containing compound (B) promotes the solid component of the resist film thickening composition to enter into the resist film, and thickens the insolubilized layer. Although not to be bound by theory, it is assumed that the nitrogen-containing compound (B) increases the adhesion to the layer under the resist film thickening film or the substrate (preferably the substrate), thereby suppressing the phenomenon that the etchant enters from the edge. If the etchant enters from the edge of the mask, the protective effect of the underlayer is reduced.

The nitrogen-containing compound (B) is preferably represented by the formula (I):

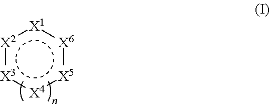

wherein

X¹ is N or NH; preferably N.

X² to X⁶ are each independently CH, CY or N, provided that one or two of X² to X⁶ are CY. Preferably, one of X² to X⁶ is CY. In a preferred embodiment, X² to X⁶ other than CY are CH. In a more preferred embodiment, X² is CY, and X³ to X⁶ are CH.

In a preferred embodiment, adjacent ring atoms are not continuously N. For example, X² and X⁶ are not N but CH or CY.
Y is each independently hydroxy (—OH), amino (—NH₂), C₁₋₄ hydroxyalkyl or C₁₋₄ aminoalkyl; preferably hydroxy, amino, hydroxymethyl, hydroxyethyl or hydroxypropyl; more preferably hydroxymethyl or hydroxyethyl; further preferably hydroxyethyl.
n is 0 or 1; preferably 1.

For clarity, in the N or C atoms of X¹ to X⁶, the remaining bonding hands bond with H.

The nitrogen-containing compound (B) is more preferably represented by the formula (Ia), (Ib) or (Ic); further preferably represented by the formula (Ia).

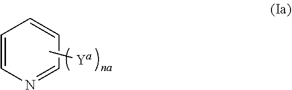

wherein
Y^{a} is each independently hydroxy, amino, C₁₋₄ hydroxyalkyl or C₁₋₄ aminoalkyl; preferably hydroxy, amino, hydroxymethyl, hydroxyethyl or hydroxypropyl; more preferably hydroxyethyl.
na is 1 or 2; preferably 1.

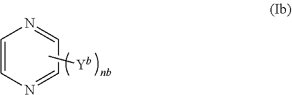

wherein
Y^{b} is each independently hydroxy, amino, C₁₋₄ hydroxyalkyl or C₁₋₄ aminoalkyl; preferably hydroxy, amino, hydroxymethyl, hydroxyethyl or hydroxypropyl; more preferably hydroxyethyl.
nb is 1 or 2; preferably 1.

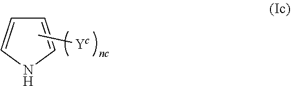

wherein
Y^{c} is each independently hydroxy, amino, C₁₋₄ hydroxyalkyl or C₁₋₄ aminoalkyl; preferably hydroxy, amino, hydroxymethyl, hydroxyethyl or hydroxypropyl; more preferably hydroxyethyl.
nc is 1 or 2; preferably 1.

Exemplified embodiments of the nitrogen-containing compound (B) are as follows.

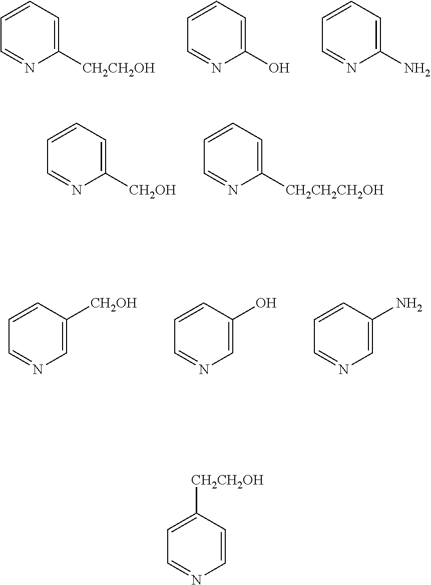

The content of the nitrogen-containing compound (B) is preferably 0.001 to 5 mass %; more preferably 0.005 to 2 mass %; further preferably 0.005 to 1 mass %, based on the total mass of the resist film thickening composition.

The content of the nitrogen-containing compound (B) is preferably 0.01 to 50 mass %; more preferably 0.05 to 20 mass %; further preferably 0.05 to 10 mass %, based on the total mass of the polymer (A).

### (C) Solvent

The solvent (C) is for dissolving the polymer (A), the nitrogen-containing compound (B) and other components used as needed. Such a solvent needs to not dissolve the resist layer.

The solvent (C) preferably comprises water. The water is preferably deionized water (DIW). Since it is used for forming a fine resist pattern, it is preferable that the solvent (C) contains few impurities. The preferred solvent (C) contains impurities of 1 ppm or less; more preferably 100 ppb or less; further preferably 10 ppb or less. For use in a fine process, it is also a preferred embodiment of the present invention to prepare a resist film thickening composition by subjecting a solution, in which solutes are dissolved, to filtration.

The content of the water is 80 to 100 mass %; more preferably 90 to 100 mass %; further preferably 98 to 100 mass %; further more preferably 100 mass %, based on the total mass of the solvent (C). In a preferred embodiment of the present invention, the solvent (C) substantially consists of only water. However, an embodiment in which an additive is contained in the resist film thickening composition according to the present invention in a state that it is dissolved and/or dispersed in a solvent other than water (for example, a surfactant) is accepted as a preferred embodiment of the present invention.

Exemplified embodiments of the solvent (C) excluding water preferably include isopropyl alcohol (IPA), cyclohexanone, cyclopentanone, propylene glycol monomethyl ether (PGME), propylene glycol monoethyl ether, propylene glycol monopropyl ether, propylene glycol monobutyl ether, propylene glycol dimethyl ether, propylene glycol diethyl ether, propylene glycol 1-monomethyl ether 2-acetate (PGMEA), propylene glycol monoethyl ether acetate, propylene glycol monopropyl ether acetate, γ-butyrolactone, ethyl lactate, or a mixture of any of these. These are preferable in terms of storage stability of the solution. Two or more kinds of these solvents can also be mixed and used. Exemplified embodiments of the solvent (C) excluding water include more preferably IPA, PGME, PGMEA, γ-butyrolactone, ethyl lactate or a mixture of any of these; further preferably IPA, PGME, PGMEA or a mixture of any of these; further more preferably IPA, PGME or PGMEA.

The content of the solvent (C) is preferably 70 to 95 mass %; more preferably 80 to 95 mass %; further preferably 85 to 95 mass %, based on the total mass of the resist film thickening composition.

The pH of the entire resist film thickening composition is preferably 5 to 12; more preferably 7 to 12, and further preferably 9 to 12.

### (D) Cross-Linking Agent

The resist film thickening composition according to the present invention can contain a cross-linking agent (D). In a preferred embodiment, the resist film thickening composition comprises a cross-linking agent (D).

The cross-linking agent (D) is preferably selected from the group consisting of a melamine-based cross-linking agent, a urea-based cross-linking agent, and an amino-based cross-linking agent.

The melamine-based cross-linking agent is preferably represented by the following formula (II).

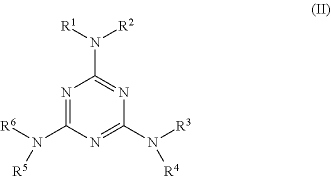

wherein
R¹, R², R³, R⁴, R⁵ and R⁶ are each independently H, methyl, ethyl, —CH₂OH, —CH₂OCH₃ or —CH₂OC₂H₅, preferably-CH₂OCH₃.

The urea-based cross-linking agent is preferably represented by the following formula (IIIa) or (IIIb).

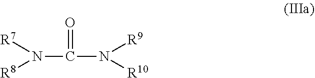

wherein
R⁷, R⁸, R⁹ and R¹⁰ are each independently H, methyl, ethyl, —CH₂OH, —CH₂OCH₃ or —CH₂O₂H₅, preferably —CH₂OCH₃.

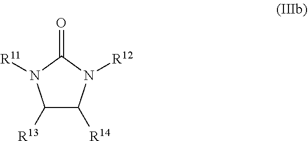

wherein
R¹¹ and R¹² are each independently H, methyl, ethyl, methoxy, ethoxy, —CH₂OH, —CH₂OCH₃ or —CH₂O₂H₅, preferably-CH₂OCH₃.
R¹³ and R¹⁴ are each independently H, hydroxy, methoxy, ethoxy and carboxy, preferably methoxy.

The amino-based cross-linking agent is preferably isocyanate, benzoguanamine and glycoluril.

It includes more preferably, methoxymethylol melamine, methoxyethylene urea, glycoluril, isocyanate, benzoguanamine, ethylene urea, ethylene urea carboxylic acid, (N-methoxymethyl)-dimethoxyethylene urea, (N-methoxymethyl)methoxyhydroxyethylene urea, N-methoxymethyl urea, or combinations of two or more cross-linking agents selected from these groups. It is preferably methoxymethylol melamine, methoxyethylene urea, (N-methoxymethyl)-dimethoxyethylene urea, (N-methoxymethyl)methoxyhydroxyethylene urea, N-methoxymethyl urea, or combinations of two or more cross-linking agents selected from these groups.

The content of the cross-linking agent (D) is preferably 0 to 10 mass %; more preferably 0.1 to 5 mass %; further preferably 0.5 to 3 mass %, based on the total mass of the resist film thickening composition.

The content of the cross-linking agent (D) is preferably 0 to 100 mass %; more preferably 1 to 50 mass %; further preferably 5 to 30 mass %, based on the total mass of the polymer (A).

### (E) Surfactant

The resist film thickening composition according to the present invention can further contain a surfactant (E). The surfactant (E) is useful for improving coatability or solubility. Examples of the surfactant that can be used in the present invention include (I) anionic surfactant, (II) cationic surfactant, or (III) nonionic surfactant, and more particularly, (I) alkyl sulfonate, alkyl benzene sulfonic acid and alkyl benzene sulfonate, (ii) lauryl pyridinium chloride and lauryl methyl ammonium chloride, and (iii) polyoxyethylene octyl ether, polyoxyethylene lauryl ether, polyoxyethylene acetylenic glycol ether, fluorine-containing surfactants (for example, Fluorad (3M), Megafac (DIC), Surflon (AGC Seimi Chemical) and organic siloxane surfactants (for example, KF-53, KP341 (Shinetsu Chemical Industry)).

These surfactants can be used alone or in combination of two or more of these.

The content of the surfactant (E) is preferably 0 to 5 mass %; more preferably 0.001 to 2 mass %; further preferably 0.01 to 1 mass %, based on the total mass of the resist film thickening composition. It is also one embodiment of the present invention that no surfactant (E) is contained (0 mass %).

### (F) Additive

The resist film thickening composition according to the present invention can further contain an additive (F) other than the above-mentioned components (A) to (E). The additive (F) is preferably a plasticizer, an acid, a basic compound, an antibacterial agent, a bactericide, a preservative, an antifungal agent, or any mixture of any of these.

The content of the additive (F) is preferably 0 to 10 mass %; more preferably 0.001 to 5 mass %; further preferably 0.001 to 1 mass %, based on the total mass of the resist film thickening composition. It is also a preferred embodiment of the present invention that the resist film thickening composition according to the present invention contain no additive (F) (0 mass %).

### [Method for Forming a Thickened Pattern]

The method for manufacturing a thickened pattern according to the present invention comprises the following steps:
(1) a step of applying a resist composition above a substrate to form a resist film;
(2a) a step of subjecting the resist film to exposure;
(2b) a step of developing the resist film to form a resist pattern;
(2c) a step of applying the resist film thickening composition according to the present invention on the surface of the resist pattern to form a resist film thickening layer;
(3) a step of heating the resist pattern and the resist film thickening layer to cure the regions of the resist film thickening layer in the vicinity of the resist pattern and to form an insolubilized layer; and
(4) a step of removing the uncured regions of the resist film thickening layer:
provided that the order of steps (2a), (2b) and (2c) is in any order, and (2a) is performed before (2b). The steps are performed preferably in the order of (2a), (2b) and (2c) or in the order of (2a), (2c) and (2b); more preferably in the order of (2a), (2b) and (2c).

Additionally, in the method for forming a thickened pattern according to the present invention, the “resist film” is a concept including a “resist layer” and a “resist pattern”. That is, the “resist film”, which is a target of thickening by the resist film thickening composition in the present invention, includes cases of both a “resist layer” and a “resist pattern”. The “resist layer” means a layer before the applied resist composition is developed; the “resist pattern” means a pattern formed by developing the resist layer. For example, when the steps are performed in the order of (2a), (2b) and (2c), the resist film before the step (2b) is a resist layer.

Hereinafter, an example of a method for manufacturing a thickened pattern according to the present invention is described for each step referring to the drawings.

### Step (1)

The step (1) is a step of applying a resist composition above a substrate to form a resist film.

The substrate to be used is not particularly limited, and examples thereof include a silicon substrate, a glass substrate, a plastic substrate, etc. Preferably, it is a large glass square substrate of 500×600 mm² or more. The substrate may be one on which surface a silicon oxide film, a metal film such as aluminum, molybdenum and chromium, a metal oxide film such as ITO, further a semiconductor device, a circuit pattern, or the like is provided as required.

Here, in the present invention, “above the substrate” includes the case where the resist composition is applied directly on a substrate and the case where the composition is applied on a substrate via one or more intervening layer. In a preferred embodiment, it is applied immediately on a substrate. Examples of the case where it is applied via another layer include an embodiment in which a resist underlayer film is formed directly above a substrate and the resist composition is applied directly above the resist underlayer film. The resist underlayer film is preferably BARC or SOC; more preferably BARC.

Examples of the application of the resist composition include methods such as slit coating and spin coating. The coating method is not limited to the method described above, and any coating method used for coating a photosensitive composition may be used. After coating the resist composition above a substrate, if necessary, the substrate is heated from 70° C. to 110° C., and the solvent component is volatilized to form a resist film. This heating may be sometimes referred to as “pre-baking” or “first heating”. The heating (this is the same in heating in the subsequent steps) can be performed using a hot plate, an oven, a furnace, or the like. The resist film to which the resist film thickening composition according to the present invention is applied preferably has a film thickness after pre-baking of 1.0 to 3.0 μm, more preferably 1.3 to 2.5 μm.

The resist composition is not particularly limited, but preferably comprises a novolak resin having an alkali dissolution rate of 100 to 3,000 Å, more preferably 400 to 1,000 Å. Resist compositions used in the field of manufacturing liquid crystal display devices are preferably used. Here, in the present invention, the alkali dissolution rate is measured from the dissolution time of the resin film with respect to an aqueous solution of 2.38% (+-1% concentration accepted) tetramethylammonium hydroxide (hereinafter referred to as TMAH). The alkali dissolution rate of the novolak resin of the resist composition used in the semiconductor manufacturing field is usually 100 Å or more and less than 400 Å.

The novolak resin is preferably known novolak resin used in a photosensitive composition comprising an alkali-soluble resin and a photosensitizer containing a quinone diazide group. The novolak resin that can be preferably used in the present invention is obtained by subjecting various phenols alone or a mixture of a plurality of these phenols to polycondensation with aldehydes such as formalin.

The resist composition of the present invention preferably contains a photosensitizer. The photosensitizer is a photosensitizer preferably having a quinone diazide group and is preferably one prepared by reacting quinone diazide sulfonic acid halides such as naphthoquinone diazide sulfonic acid chloride and benzoquinone diazide sulfonic acid chloride with a low molecular weight compound or polymer compound having a functional group capable of condensation reaction with this acid halide. The functional group capable of condensing with the acid halide includes a hydroxy group, an amino group and the like, and a hydroxy group is particularly preferable. Examples of the low molecular compound having a hydroxy group include hydroquinone, resorcin, 2,4-dihydroxybenzophenone, 2,3,4-trihydroxybenzo-phenone, 2,4,6-trihydroxybenzophenone, 2,4,4′-tri-hydroxybenzophenone, 2,3,4,4′-tetrahydroxybenzo-phenone, 2,2′, 4,4′-tetrahydroxybenzophenone, 2,2′, 3,4,6′-pentahydroxybenzophenone and the like, and examples of the polymer compound having a hydroxy group include novolak resin, polyvinyl phenol and the like. The reactant of the quinonediazide sulfonic acid halide and the compound having a hydroxy group may be a single esterified product or a mixture of two or more different compounds having different esterification ratios. In the present invention, these photosensitizers having a quinone diazide group are usually used in an amount of 1 to 30 mass parts, preferably 15 to 25 mass parts, based on 100 mass parts of the resin component in the photosensitive composition.

The resist composition used in the present invention contains a solvent. Examples of the solvent include ethylene glycol monoalkyl ethers such as ethylene glycol monomethyl ether and ethylene glycol monoethyl ether; ethylene glycol monoalkyl ether acetates such as ethylene glycol monomethyl ether acetate and ethylene glycol monoethyl ether acetate; propylene glycol monoalkyl ethers such as propylene glycol monomethyl ether and propylene glycol monoethyl ether; propylene glycol monoalkyl ether acetates such as propylene glycol monomethyl ether acetate and propylene glycol monoethyl ether acetate; lactates such as methyl lactate and ethyl lactate; aromatic hydrocarbons such as toluene and xylene; ketones such as methyl ethyl ketone, 2-heptanone and cyclohexanone; amides such as N,N-dimethylacetamide and N-methylpyrrolidone; lactones such as γ-butyrolactone. These solvents can be used alone or in combination of two or more.

The compounding ratio of the solvent varies depending on the coating method and the requirement for the film thickness after coating. For example, in the case of spray coating, it becomes 90% or more based on the total mass of the novolak resin, the photosensitizer and optional components, but in the case of slit coating of a large glass substrate used for manufacturing displays, it is 50% or more (preferably 60% or more), and/or 90% or less, and (preferably 85% or less).

The resist composition of the present invention may be a positive type or a negative type; preferably a positive type.

Examples of other components that may be contained in the resist composition used in the present invention include a surfactant, an adhesion enhancer, and the like.

### Step (2a)

The step (2a) is a step of subjecting the resist film to exposure. The resist composition layer is exposed for patterning through a desired mask. The exposure wavelength used at this time may be any one of a single wavelength such as g-line (436 nm), h-line (405 nm), and i-line (365 nm), which are used for exposing the resist composition, a wavelength mixture of g-line and h-line, and one in which i-line, h-line and g-line are mixed, which is called broadband, and the like. The wavelength included in the exposure is 13.5 to 450 nm; preferably 248 to 450 nm; more preferably 300 to 450 nm; further preferably 350 to 450 nm. The exposure amount is preferably 15 to 80 mJ/cm²; more preferably 20 to 60 mJ/cm².

In the present invention, an exposure apparatus having a resolution limit of 1.5 to 5.0 μm, more preferably 1.5 to 4.0 μm, is suitable. Here, the resolution limit in the present invention is defined in the same manner as described in Patent Document 1

It is preferable that the exposure in the step (2a) is performed using an exposure apparatus having a resolution limit of 1.5 to 5.0 μm.

The exposure is preferably performed using a projector lens having a numerical aperture NA of 0.08 to 0.15 (preferably 0.083 to 0.145; more preferably 0.083 to 0.10). In the case of not using a lens for exposure (so-called mirror projection system), strictly speaking, NA does not exist, but interpretation is made by replacing with the numerical aperture NA of the case that the above-mentioned resolution limit is about the same. It is preferable that the exposure in the step (2a) is performed using a projection lens having a numerical aperture of 0.08 to 0.15.

### Step (2b)

The step (2b) is a step of developing the resist film to form a resist pattern. In a preferable embodiment of the case of the positive type, after the exposure, by developing with an alkali developer, the exposed regions are dissolved and only the unexposed regions are left to form a positive pattern. As the alkali developer, an aqueous solution of a quaternary amine such as TMAH and an aqueous solution of an inorganic hydroxide such as sodium hydroxide and potassium hydroxide are generally used. Here, the exposed regions are dissolved into the developer, the unexposed regions are left on the substrate, and a resist pattern is formed.

A step of heating the resist pattern can be further contained after forming the resist pattern and before applying the resist film thickening composition. This heating may be sometimes referred to as “post-baking” or “second heating”. The purpose of this post-baking is to improve etching resistance. The temperature of post-baking is preferably 110 to 150° C., more preferably 130 to 140° C. The post-baking time is, in the case of a hot plate, preferably 30 to 300 seconds, more preferably 60 to 180 seconds.

It is also a preferable embodiment of the method for manufacturing a thickened pattern of the present invention that the method includes a step (2b)-2 of subjecting the resist pattern to flood exposure after the step (2b) of developing a resist layer to form a resist pattern. Preferred examples of the conditions of the resolution limit and the numerical aperture of the exposure in the step (2b)-2 is the same as those of (2a) described above.

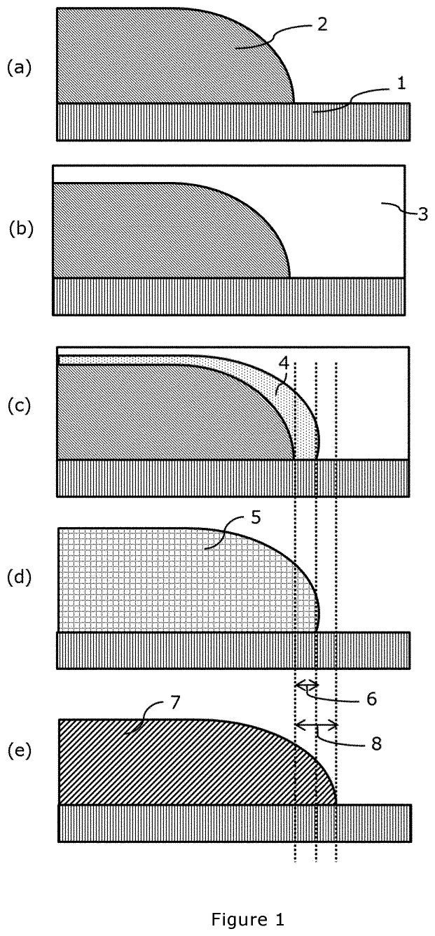

Hereinafter, the present invention is described referring to the drawings. In FIG. 1, the steps are performed in the order of (2a), (2b) and (2c). FIG. 1(a) shows a state in which the resist pattern 2 is formed on the substrate 1. The cross section shape of the resist pattern is preferably a taper shape. In the present invention, when the resist pattern has a taper shape, the gently-sloping shape is transferred when a wiring processing is performed by subsequent dry etching or the like.

It is also preferable to further contain the step (2b)-2 of subjecting the resist pattern, which is post-baked as needed, to flood exposure. Flood exposure is performed with an exposure wavelength of 350 to 450 nm via no mask or using a blank mask (all light is transmitted). By performing flood exposure, the regions which were the unexposed regions at the time of the first patterning exposure is exposed, so that an acid is generated from the photosensitizer. It is assumed that this acid functions as a catalyst to promote cross-linking when an insolubilized layer is formed.

### Step (2c)

The step (2c) is a step of applying the resist film thickening composition on the surface of the resist pattern to form a resist film thickening layer. Application of the resist film thickening composition may be conducted by any known method, but it is preferably conducted by the same method as in the application of the resist composition. At this time, the film thickness of the resist film thickening composition may be of any amount. In an embodiment of the present invention, the film thickness when applied on bare silicon is preferably 50 nm to 10 μm; more preferably 1.0 to 8.0 μm; further preferably 3.0 to 6.0 μm. After application, pre-baking is conducted as needed (for example, at 60 to 90° C. and for 15 to 90 seconds) to form a resist film thickening layer. FIG. 1(b) shows a state in which a resist film thickening composition is applied on the formed resist pattern to form a resist film thickening layer 3.

### Step (3)

The step (3) is a step of heating the resist pattern and the resist film thickening layer to cure the regions of the resist film thickening layer in the vicinity of the resist pattern and to form an insolubilized layer 4. The heating in this step may be sometimes referred to as “mixing baking” or “third heating”. FIG. 1(c) shows a state in which an insolubilized layer 4 is formed after mixing baking the formed resist film thickening layer and the resist pattern. By the mixing baking, for example, the polymer in the resist composition and the polymer in the resist film thickening layer are mixed or cross-linked by a cross-linking agent, the regions in the vicinity of the resist pattern are cured, and an insolubilized layer is formed. The temperature and the baking time of the mixing baking are appropriately determined depending on the resist to be used, the material used in the resist film thickening composition, the line width of the target fine pattern, and the like. The temperature of the mixing baking is preferably 50 to 140° C.; more preferably 80 to 120° C. The baking time is preferably 90 to 300 seconds; more preferably 150 to 240 seconds.

### Step (4)

The step (4) is a step of removing the uncured regions of the resist film thickening layer. FIG. 1(d) shows a state in which the uncured regions of the resist film thickening layer are removed to form a thickened pattern 5. The method of removing the uncured regions is not particularly limited, but it is preferable to remove them by contacting the resist film thickening layer and water, a liquid mixture of water and a water-soluble organic solvent, or an alkali aqueous solution. An aqueous solution containing isopropyl alcohol and an aqueous solution containing TMAH are more preferably used. Depending on the removal conditions, the thickness of the insolubilized layer may change. For example, by prolonging the contact time with the liquid, the thickness of the insolubilized layer may become thinner. Through the above processing, the space portion of the pattern is effectively miniaturized, and a thickened pattern can be obtained.

Here, as shown in FIG. 1(d), the distance between the bottom position of the resist pattern and the bottom position of the thickened pattern is defined as a shrink amount 6. The shrink amount can be measured, for example, by measuring the space width or the hole diameter at the bottom of the resist pattern with respect to four points by cross-section observation to obtain the average space width or hole diameter (S¹), and similarly measuring the average space width or the hole diameter (S²) after formation of the fine pattern. The value obtained by dividing S²-S¹ by 2 can be calculated as the shrink amount.

The cross section shape of the thickened pattern is preferably a taper shape.

After the step (4), it is also preferable to further contain a step (4)-2 of further heating the thickened pattern to deform the pattern. In the present invention, this step (4)-2 may be sometimes referred to as “second post-baking” or “fourth heating”. By the step (4)-2, the space portion of the thickened pattern can be further thickened to obtain a thickened pattern 7. In the step (4)-2, it is assumed that heat flow occurs in the thickened pattern to induce deformation of the pattern. The temperature of the second post-baking is preferably 100 to 145° C.; more preferably 120 to 130° C. The baking time is preferably 90 to 300 seconds; more preferably 150 to 240 seconds.

FIG. 1(e) shows a state in which the thickening pattern 7 is formed after the second post-baking. When the step (4)-2 is performed, as shown in FIG. 1(e), the distance between the bottom position of the resist pattern and the bottom position of the thickened pattern after the second baking is defined as a shrink amount 8. Although not to be bound by theory, it is assumed that including the nitrogen-containing compound (B) lowers the softening point of the thickened pattern, facilitates flow, and increases the shrink amount.

### [Method for Manufacturing a Processed Substrate]

The method for manufacturing a processed substrate according to the present invention comprises the following steps:
a step of preparing a substrate above which a thickened pattern is formed by the above-described method; and (5) a step of processing the substrate by etching.

### Step (5)

In the step (5), the substrate may be directly processed using the thickened pattern as a mask. In another embodiment, there is also a method of etching the lower layer using the thickened pattern as a mask and processing the substrate using the etched lower layer as a mask.

Preferably, in the step (5), the substrate is directly processed using the thickened pattern as a mask. Various substrates to be an underlying can be processed by means of dry etching method, wet etching method, ion implantation method, metal plating method, or the like. For example, a substrate may be etched by dry etching or wet etching to form a recess, which may be filled with a conductive material to form a circuit structure, or a metal layer may be formed by means of metal plating method in the regions uncovered by the thickened pattern to form a circuit structure. According to the method according to the present invention, the adhesion between the thickened pattern and the underlying substrate can be increased, which is suitable for wet etching. Since it is a thick film, using it for dry etching is also a preferable embodiment.

The thickened pattern is removed in the process of processing the substrate. If necessary, the substrate is processed to form a wiring and a device is manufactured. The device is preferably a semiconductor device or a display device; more preferably a display device. In the present invention, the display device means a device which displays an image (including characters) on the display surface. The display device is preferably flat panel display (FPD). The FPD is preferably liquid crystal display, plasma display, organic EL (OLED) display, field emission display (FED); more preferably liquid crystal display.

### Examples

The present invention is described below by use of Examples. Additionally, the embodiment of the present invention is not limited only to these Examples.

### [Preparation of Comparative Composition A]

One regulated the solid component of AZ R200 (Merck Electronics, hereinafter referred to as Merck) to be 9.9 mass % is prepared, and this is taken as Comparative Composition A (hereinafter, sometimes refers to as AZ R200 (9.9 mass %)).

AZ R200 contains polyvinyl alcohol resin and water, and does not contain any nitrogen-containing compound (B).

### [Preparation of Resist Film Thickening Composition A]

0.083 mass parts of 2-pyridineethanol is dissolved as a nitrogen-containing compound (B) in 100 mass parts of AZ R²⁰⁰ (9.9 mass %). The obtained solution is filtered through a 0.2 μm fluororesin filter to obtain Resist Film Thickening Composition A.

### [Preparation of Resist Film Thickening Composition B]

Resist Film Thickening Composition B is obtained in the same manner as in the above preparation of Resist Film Thickening Composition A described above, except that the amount of 2-pyridineethanol is changed from 0.083 mass parts to 0.165 mass parts.

### [Preparation of Comparative Composition B]

Comparative Composition B is obtained in the same manner as in the preparation of Resist Film Thickening Composition A described above, except that 0.083 mass parts of 2-pyridineethanol is changed to 0.083 mass parts of diethylaniline.

[Preparation of Resist Film Thickening Compositions C to E and Comparative Composition C]

The polymer (A), the nitrogen-containing compound (B), the cross-linking agent (D) and the surfactant (E) shown in Table 1 are dissolved in the solvent (C). The obtained solution is filtered through a 0.2 μm fluororesin filter to obtain Resist Film Thickening Compositions C to E and Comparative Composition C, respectively.

TABLE 1

| | | Resist film | Resist film | Resist film | |
|---|---|---|---|---|---|
| | | thickening | thickening | thickening | Comparative |
| | | composition C | composition D | composition E | composition C |
| Polymer (A) | V-7154 | 8.73 | 8.45 | 8.66 | 8.8 |
| Nitrogen-containing compound (B) | 2-Pyridineethanol | 0.087 | 0.422 | 0.173 | — |
| Solvent (C) | Water | 89.5 | 89.5 | 89.5 | 89.5 |
| Cross-linking agent (D) | Nikalac MX-280 | 1.66 | 1.61 | 1.65 | 1.67 |
| Surfactant (E) | Surflon S-231 | 0.026 | 0.025 | 0.026 | 0.026 |

The components in the table are described below.
V-7154: polyvinyl alcohol-polyvinylpyrrolidone graft copolymer, DKS
Nikalac MX-280: Sanwa Chemical

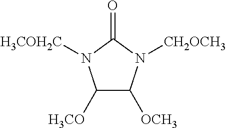

Surflon S-231: perfluoroalkyl betaine (number of carbon atoms of alkyl group: 6), AGC Seimi Chemical

### [Shrink Amount Evaluation 1]

AZ SFP-1500 (10 cP) (Merck), which is a resist composition, is applied on a 4-inch silicon wafer using a spin coater (Dual-1000, Lithotech Japan), and prebaked on a hot plate at 110° C. for 160 seconds, thereby forming a resist layer. Additionally, the alkali dissolution rate of the novolak resin in AZ SFP-1500 (10 cP) is about 500 Å. The film thickness of the resist layer after prebaking is 1.5 μm.

Next, theoretically, a mask is set so that the line=3.0 μm and the space=3.0 μm, and using a stepper (NES2W-ghi06 (NA=0.13), Nikon Engineering), the resist layer is exposed at 22.0 mJ/cm² with a wavelength mixture of g-line and h-line. The resist layer is developed with 2.38% TMAH developer of 23° C. for 60 seconds to form a resist pattern. The obtained resist pattern is post-baked on a hot plate at 140° C. for 180 seconds. When a section for SEM is prepared at this point, the line width is 2.87 μm.

The resist pattern after post-baking is subjected to flood exposure with an exposure apparatus (PLA-501F, Canon). The wavelength at this time is a wavelength mixture of g-line, h-line and i-line. Resist Film Thickening Composition A is applied on the surface of the resist pattern using a spin coater (MS-A100, Mikasa) to form a resist film thickening layer. The resist film thickening layer is subjected to mixing baking on a hot plate at 100° C. for 180 seconds, thereby forming an insolubilized layer. The film thickness after mixing baking is 3.0 μm. By developing with R2 Developer (Merck), the uncured regions are removed, thereby obtaining a thickened pattern. The obtained thickened pattern is post-baked on a hot plate at 140° C. for 180 seconds to deform the thickened pattern. When a section for SEM is prepared at this point, the line width is 4.28 μm, and the shrink amount is calculated to be 0.71 μm.

The shrink width is calculated in the same manner as described above, except that Resist Film Thickening Composition A is changed to Resist Film Thickening Composition B and Comparative Compositions A and B. The results obtained are shown in Table 2. It is confirmed that with use of the resist film thickening compositions, which are the examples containing the nitrogen-containing compound (B) of the present invention, the shrink amount can be increased as compared with the comparative compositions.

TABLE 2

| | Resist film | Resist film | | |
|---|---|---|---|---|
| | thickening | thickening | Comparative | Comparative |
| | composition | composition | composition | composition |
| | A | B | A | B |
| Shrink | 0.71 | 0.72 | 0.44 | 0.46 |
| amount (μm) | | | | |

### [Shrink Amount Evaluation 2]

AZ SFP-1500 (10 cP), which is a resist composition, is applied on a 4-inch silicon wafer using a spin coater (Dual-1000, Lithotech Japan), and prebaked on a hot plate at 110° C. for 160 seconds, thereby forming a resist layer. The film thickness of the resist layer after prebaking is 1.5 μm.

Next, theoretically, a mask is set so that the line=3.0 μm and the space=3.0 μm, and using a stepper (NES2W-ghi06 (NA=0.13)), the resist layer is exposed at 22.0 mJ/cm² with a wavelength mixture of g-line and h-line. The resist layer is developed with 2.38% TMAH developer of 23° C. for 60 seconds to form a resist pattern. The obtained resist pattern is post-baked on a hot plate at 140° C. for 180 seconds. When a section for SEM is prepared at this point, the line width is 2.79 μm.

The resist pattern after post-baking is subjected to flood exposure with an exposure apparatus (PLA-501F). The wavelength at this time is a wavelength mixture of g-line, h-line and i-line. Resist Film Thickening Composition C is applied on the surface of the resist pattern using a spin coater (MS-A100) to form a resist film thickening layer. The resist film thickening layer is subjected to mixing baking on a hot plate at 100° C. for 180 seconds, thereby forming an insolubilized layer. The film thickness after mixing baking is 3.0 μm. By developing with DIW, the uncured regions are removed, thereby obtaining a thickened pattern. The obtained thickened pattern is post-baked on a hot plate at 140° C. for 180 seconds to deform the thickened pattern. When a section for SEM is prepared at this point, the line width is 3.31 μm, and the shrink amount is calculated to be 0.26 μm.

The shrink width is calculated in the same manner as described above, except that Resist Film Thickening Composition C is changed to Resist Film Thickening Composition D or Comparative Composition C. The results obtained are shown in Table 3. It is confirmed that with use of the resist film thickening compositions, which are the examples containing the nitrogen-containing compound (B) of the present invention, the shrink amount can be increased as compared with the comparative composition.

TABLE 3

| | Resist film | Resist film | |
|---|---|---|---|
| | thickening | thickening | Comparative |
| | composition C | composition D | composition C |
| Shrink amount (μm) | 0.26 | 0.43 | 0.22 |

### [Adhesion Evaluation 1]

AZ SFP-1500 (10 cP), which is a resist composition, is applied on an ITO film-formed substrate (10 cP) using a spin coater (Dual-1000) and prebaked on a hot plate at 110° C. for 160 seconds, thereby forming a resist layer. The film thickness of the resist layer after prebaking is 1.5 μm.

Next, theoretically, a mask is set so that the line=6.0 μm and the space=6.0 μm, and using a stepper (NES2W-ghi06 (NA=0.13)), the resist layer is exposed at 22.0 mJ/cm² with a wavelength mixture of g-line and h-line. The resist layer is developed with 2.38% TMAH developer of 23° C. for 60 seconds to form a resist pattern. The obtained resist pattern is post-baked on a hot plate at 140° C. for 180 seconds. When a section for SEM is prepared at this point, the line width is 6.08 μm.

The resist pattern after post-baking is subjected to flood exposure with an exposure apparatus (PLA-501F). The wavelength at this time is a wavelength mixture of g-line, h-line and i-line. Resist Film Thickening Composition A is applied on the surface of the resist pattern using a spin coater (MS-A100) to form a resist film thickening layer. The resist film thickening layer is subjected to mixing baking on a hot plate at 100° C. for 180 seconds, thereby forming an insolubilized layer. The film thickness after mixing baking is 3.0 μm. By developing with R2 Developer (Merck), the uncured regions are removed, thereby obtaining a thickened pattern. The obtained thickened pattern is post-baked on a hot plate at 150° C. for 180 seconds to deform the thickened pattern. When a section for SEM is prepared at this point, the line width is 6.81 μm, and the shrink amount is calculated to be 0.37 μm.

The obtained thickened pattern is etched with an ITO etchant (hydrochloric acid/iron (III) chloride) of 23° C. for 3 times the time of just-etching. Here, the just-etching means the time when the ITO layer disappears, the surface of the underlying layer appears, and the etching is just completed.

After that, the remaining thickened pattern is removed by treating with TOK-106 (Tokyo Ohka Kogyo) of 40° C. for 180 seconds to obtain a metal wiring. When a section for SEM is prepared at this point, the line width of the metal wiring is 4.66 μm.

The calculation of the shrink width and the measurement of the line width of the metal wiring are conducted in the same manner as described above, except that Resist Film Thickening Composition A is changed to Resist Film Thickening Composition B and Comparative Compositions A and B. The results obtained are shown in Table 4.

It is confirmed that with use of the resist film thickening compositions, which are the examples containing the nitrogen-containing compound (B) of the present invention, the shrink amount can be increased and the line width of the metal wiring can be increased as compared with the comparative compositions.

TABLE 4

| | Resist film | Resist film | | |
|---|---|---|---|---|
| | thickening | thickening | Comparative | Comparative |
| | composition | composition | composition | composition |
| | A | B | A | B |
| Shrink | 0.37 | 0.44 | 0.28 | 0.29 |
| amount (μm) | | | | |
| Line width | 4.66 | 4.75 | 3.98 | 3.94 |
| of the metal | | | | |
| wiring (μm) | | | | |

### [Adhesion Evaluation 2]

AZ SFP-1500 (10 cP), which is a resist composition, is applied on a Cr film-formed substrate (10 cP) using a spin coater (Dual-1000) and prebaked on a hot plate at 110° C. for 160 seconds, thereby forming a resist layer. The film thickness of the resist layer after prebaking is 1.5 μm.

Next, theoretically, a mask is set so that the line=6.0 μm and the space=6.0 μm, and using a stepper (NES2W-ghi06 (NA=0.13)), the resist layer is exposed at 22.0 mJ/cm² with a wavelength mixture of g-line and h-line. The resist layer is developed with 2.38% TMAH developer of 23° C. for 60 seconds to form a resist pattern. The obtained resist pattern is post-baked on a hot plate at 140° C. for 180 seconds. When a section for SEM is prepared at this point, the line width is 6.33 μm.

The resist pattern after post-baking is subjected to flood exposure with an exposure apparatus (PLA-501F). The wavelength at this time is a wavelength mixture of g-line, h-line and i-line. Resist Film Thickening Composition C is applied on the surface of the resist pattern using a spin coater (MS-A100) to form a resist film thickening layer. The resist film thickening layer is subjected to mixing baking on a hot plate at 100° C. for 180 seconds, thereby forming an insolubilized layer. The film thickness after mixing baking is 3.0 μm. By developing with DIW, the uncured regions are removed, thereby obtaining a thickened pattern. The obtained thickened pattern is post-baked on a hot plate at 150° C. for 180 seconds to deform the thickened pattern. When a section for SEM is prepared at this point, the line width is 6.80 μm, and the shrink amount is calculated to be 0.24 μm.

The obtained thickened pattern is etched with a Cr etchant (Kanto Chemical) of 23° C. for 3 times the time of just-etching. Here, the just-etching means the time when the Cr layer disappears, the surface of the underlying layer appears, and the etching is just completed.

After that, the remaining thickened pattern is removed by treating with TOK-106 of 40° C. for 180 seconds to obtain a metal wiring. When a section for SEM is prepared at this point, the line width of the metal wiring is 5.24 μm.

The calculation of the shrink width and the measurement of the line width of the metal wiring are conducted in the same manner as described above, except that Resist Film Thickening Composition C is changed to Resist Film Thickening Composition E or Comparative Composition C. The results obtained are shown in Table 5.

It is confirmed that with use of Resist Film Thickening Composition E, which is the example containing the nitrogen-containing compound (B) of the present invention, the shrink amount can be increased and the line width of the metal wiring can be increased as compared with Comparative Composition C. It is confirmed that with use of Resist Film Thickening Composition C, which is the example containing the nitrogen-containing compound (B) of the present invention, the shrink amount is slightly smaller, but the line width of the metal wiring can be increased, as compared with Comparative Composition C. Although not to be bound by theory, it is assumed that when Resist Film Thickening Composition C is used, the thickened pattern or insolubilized layer formed has good adhesion to the substrate, so that the etchant does not enter from the bottom of the pattern and the function as a mask can be fulfilled more effectively.

TABLE 5

| | Resist film | Resist film | |
|---|---|---|---|
| | thickening | thickening | Comparative |
| | composition C | composition E | composition C |
| Shrink amount (μm) | 0.24 | 0.30 | 0.26 |
| Line width of the | 5.24 | 5.33 | 4.83 |
| metal wiring (μm) | | | |

### EXPLANATION OF SYMBOLS

1. substrate
2. resist pattern
3. resist film thickening layer
4. insolubilized layer
5. thickened pattern
6. shrink amount
7. thickened pattern
8. shrink amount

1.-15. (canceled)

16. A resist film thickening composition comprising a polymer (A), a nitrogen-containing compound (B) and a solvent (C):
wherein
the nitrogen-containing compound (B) is a 5- or 6-membered nitrogen-containing unsaturated heterocyclic compound substituted with one or two substituents selected from the group consisting of hydroxy, amino, C₁₋₄ hydroxyalkyl and C₁₋₄ aminoalkyl.

17. The composition according to claim 16, wherein the nitrogen-containing compound (B) is represented by the formula (I): 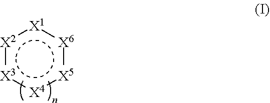
wherein
X¹ is N or NH,
X² to X⁶ are each independently CH, CY or N, provided that one or two of X² to X⁶ are CY, Y is each independently hydroxy (—OH), amino (—NH₂), C₁₋₄ hydroxyalkyl or C₁₋₄ aminoalkyl, and
n is 0 or 1.

18. The composition according to claim 16, wherein the nitrogen-containing compound (B) is represented by the formula (Ia), (Ib) or (Ic): 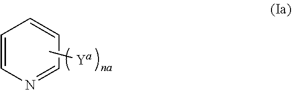
wherein
Y^{a} is each independently hydroxy, amino, C₁₋₄ hydroxyalkyl or C₁₋₄ aminoalkyl, and na is 1 or 2; 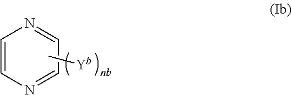
wherein
Y^{b} is each independently hydroxy, amino, C₁₋₄ hydroxyalkyl or C₁₋₄ aminoalkyl, and nb is 1 or 2; and 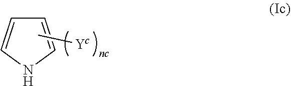
wherein
Y^{c} is each independently hydroxy, amino, C₁₋₄ hydroxyalkyl or C₁₋₄ aminoalkyl, and nc is 1 or 2.

19. The composition according to claim 16, wherein the polymer (A) is selected from the group consisting of polyvinyl acetal resin, polyvinyl alcohol resin, polyacrylic acid resin, polyvinylpyrrolidone resin, polyethylene oxide resin, poly-N-vinylformamide resin, oxazoline-containing water-soluble resin, aqueous urethane resin, polyallylamine resin, polyethyleneimine resin, polyvinylamine resin, water-soluble phenol resin, water-soluble epoxy resin, polyethyleneimine resin, and copolymers of any of these, and styrene-maleic acid copolymer.

20. The composition according to claim 16, wherein the solvent (C) comprises water.

21. The composition according to claim 20, wherein the content of the water is 80 to 100 mass % based on the total mass of the solvent (C);
the content of the polymer (A) is 5 to 30 mass % based on the total mass of the composition;
the content of the nitrogen-containing compound (B) is 0.001 to 5 mass % based on the total mass of the composition.

22. The composition according to claim 16, wherein
the solvent (C) comprises water and the content of the water is 98 to 100 mass %, based on the total mass of the solvent (C);
the content of the polymer (A) is 8 to 15 mass %) based on the total mass of the composition;
the content of the nitrogen-containing compound (B) is 0.005 to 1 mass %) based on the total mass of the composition; or
the content of the solvent (C) is 85 to 95 mass % based on the total mass of the composition.

23. The composition according to claim 16, further comprising a cross-linking agent (D).

24. The composition according to claim 23, wherein the cross-linking agent (D) is selected from the group consisting of a melamine-based cross-linking agent, a urea-based cross-linking agent, and an amino-based cross-linking agent.

25. The composition according to claim 23, wherein the cross-linking agent (D) is selected from the group consisting of a melamine-based cross-linking agent, a urea-based cross-linking agent, and an amino-based cross-linking agent; and
the content of the cross-linking agent (D) is 0.1 to 5 mass % based on the total mass of the composition.

26. The composition according to claim 16, further comprising a surfactant (E) and/or an additive (F).

27. The composition according to claim 26, wherein the content of the surfactant (E) is 0.001 to 5 mass %, based on the total mass of the composition; and
the additive (F) is a plasticizer, an acid, a basic compound, an antibacterial agent, a bactericide, a preservative, an antifungal agent, or any mixture of any of these; or
the content of the additive (F) is 0.001 to 10 mass % (based on the total mass of the composition.

28. The composition according to claim 16, which is a fine pattern forming composition.

29. A method for manufacturing a thickened pattern comprising the following steps:
(1) a step of applying a resist composition above a substrate to form a resist film;
(2a) a step of subjecting the resist film to exposure;
(2b) a step of developing the resist film to form a resist pattern;
(2c) a step of applying the resist film thickening composition according to claim 16 on the surface of the resist pattern to form a resist film thickening layer;
(3) a step of heating the resist pattern and the resist film thickening layer to cure the regions of the resist film thickening layer in the vicinity of the resist pattern and to form an insolubilized layer; and
(4) a step of removing the uncured regions of the resist film thickening layer:
provided that the order of steps (2a), (2b) and (2c) is in any order, and (2a) is performed before (2b).

30. The method for manufacturing a thickened pattern according to claim 29, wherein the steps are performed in the order of (2a), (2b) and (2c).

31. The method according to claim 29, wherein the exposure in the step (2a) is performed using an exposure apparatus having a resolution limit of 1.5 to 5.0 μm.

32. The method according to claim 29, wherein the exposure in the step (2a) is performed using a projector lens having a numerical aperture of 0.08 to 0.15.

33. The method according to claim 29, wherein the light irradiated in the step (2a) comprises wavelength of 300 to 450 nm.

34. A method for manufacturing a processed substrate comprising the following steps: a step of preparing a substrate above which a thickened pattern is formed by the method according to claim 29; and
(5) a step of processing the substrate by etching.

35. A method for manufacturing a device comprising the method according to claim 29; and a step of forming a wiring on the substrate is further comprised; or
the device is a display device.
